(19) United States
(12) Patent Application Publication
(10) Pub. No.: US 2023/0167252 A1
(43) Pub. Date: Jun. 1, 2023

(54) RESIN FILM, METHOD FOR PRODUCING SAME, RESIN COMPOSITION, DISPLAY AND METHOD FOR PRODUCING SAME

(71) Applicant: Toray Industries, Inc., Tokyo (JP)

(72) Inventors: Tomoki Ashibe, Otsu-shi, Shiga (JP); Daichi Miyazaki, Otsu-shi, Shiga (JP); Mitsuhito Suwa, Otsu-shi, Shiga (JP)

(73) Assignee: Toray Industries, Inc., Tokyo (JP)

(21) Appl. No.: 17/913,294

(22) PCT Filed: Mar. 22, 2021
(86) PCT No.: PCT/JP2021/011710

§ 371 Date: Sep. 21, 2022

(30) Foreign Application Priority Data
Mar. 24, 2020 (JP) 2020-052296

(51) Int. Cl. C08J 5/18; C08G 73/10; H10K 59/12

(52) U.S. Cl. CPC C08J 5/18; C08G 73/106; H10K 59/1201; C08J 2379/08

(57) ABSTRACT

The present invention provides a resin film that is less likely to suffer peeling or creasing of a layer formed on the resin film in a high temperature process for producing a device and that can be used suitably to produce a product that requires transparency, where the resin film comprises a resin that has a repeating unit as represented by the chemical formula (1) and has a light transmittance of 68% or more at a wavelength of 400 nm, a glass transition temperature of 370° C. or more, and a weight loss starting temperature of 440° C. or more,

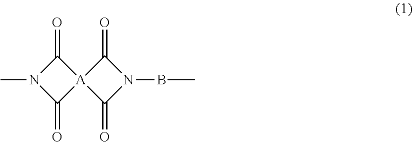

where in the chemical formula (1), A denotes a tetravalent tetracarboxylic acid residue containing 2 or more carbon atoms and B denotes a divalent diamine residue containing 2 or more carbon atoms.

### CROSS REFERENCE TO RELATED APPLICATIONS

This application is the U.S. National Phase application of PCT/JP2021/011710, filed Mar. 22, 2021, which claims priority to Japanese Patent Application No. 2020-052296, filed Mar. 24, 2020, the disclosures of these applications being incorporated herein by reference in their entireties for all purposes.

### FIELD OF THE INVENTION

The present invention relates to a resin film, a production method therefor, a resin composition, a display, and a production method therefor.

### BACKGROUND OF THE INVENTION

Having good electrical insulation properties, heat resistance, and mechanical properties, polyimide has been used as material for various electronic devices such as semiconductors and display devices. Recently, production of shock resistant, flexible displays has become possible by applying polyimide film to the substrates of image display devices such as organic EL displays, electronic papers, and color filters.

Materials to be incorporated in electronic devices are required to be so high in heat resistance as to resist high temperature processes used for device production. To produce a product that requires transparency, in particular, it is necessary to adopt a material that is high in both heat resistance and transparency.

For example, Patent document 1 proposes a process for producing an organic EL display by using a polyimide substrate with high heat resistance. Patent document 2 further proposes a process for producing electronic devices such as color filter, organic EL display, and touch panel by using a polyimide substrate with high transparency. In addition, Patent document 3 reports a process for using an alkoxysilane modified polyimide precursor to produce a polyimide film that serves as a transparent substrate.

### PATENT DOCUMENTS

Patent document 1: International Publication WO 2017/099183
Patent document 2: International Publication WO 2017/221776
Patent document 3: Japanese Unexamined Patent Publication (Kokai) No. 2016-188367

### SUMMARY OF THE INVENTION

In the case of the polyimide resin film described in Patent document 1, the resin film fails to have a sufficiently high light transmittance and therefore it has the disadvantage of being unsuitable for producing products that require transparency. The polyimide resin films described in Patent document 2 and Patent document 3 are disadvantageous in that layers formed on the polyimide resin films are likely to be peeled or layers formed thereon are likely to suffer creasing in high temperature processes implemented for producing electronic devices. Thus, the main object of the present invention is to provide a resin film having transparency and characterized in that layers formed on the resin film will not be peeled or creased in high temperature processes.

The present invention relates to a resin film containing a resin that has a repeating unit as represented by the chemical formula (1) and is characterized by having a light transmittance of 68% or more at a wavelength of 400 nm, a glass transition temperature (hereinafter referred to as Tg when appropriate) of 370° C. or more, and a weight loss starting temperature (hereinafter referred to as Td₀ when appropriate) of 440° C. or more.

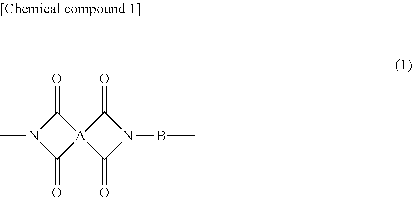

In the chemical formula (1), A denotes a tetravalent tetracarboxylic acid residue containing 2 or more carbon atoms and B denotes a divalent diamine residue containing 2 or more carbon atoms.

The present invention also relates to a resin composition that contains a resin having a repeating unit as represented by the chemical formula (4) and a solvent and is characterized by serving to form, when being spread and baked at 410° C., a 10 μm thick resin film having a light transmittance of 68% or more at a wavelength of 400 nm, a Tg of 370° C. or more, and a Td₀ of 440° C. or more.

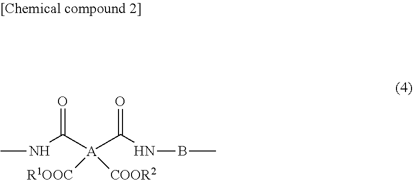

In the chemical formula (4), A denotes a tetravalent tetracarboxylic acid residue containing 2 or more carbon atoms and B denotes a divalent diamine residue containing 2 or more carbon atoms.

R¹ and R² each independently denote a hydrogen atom, a hydrocarbon group containing 1 to 10 carbon atoms, an alkyl silyl group containing 1 to 10 carbon atoms, an alkali metal ion, an ammonium ion, an imidazolium ion, or a pyridinium ion.

If a layer is formed on the resin film according to the present invention, the layer on the resin film is less likely to suffer from peeling or creasing in a high temperature process for producing an electronic device, and it can be used suitably to produce a product that requires transparency.

### DETAILED DESCRIPTION OF EMBODIMENTS OF THE INVENTION

Embodiments of the present invention are described in detail below. It should be noted, however, that the present invention is not limited to the embodiments described below and may be modified appropriately to suit particular objectives and purposes.

### <Resin Film>

The resin film according to the present invention is a resin film containing a resin that has a repeating unit as represented by the chemical formula (1) and is characterized by having a light transmittance of 68% or more at a wavelength of 400 nm, a glass transition temperature of 370° C. or more, and a weight loss starting temperature of 440° C. or more.

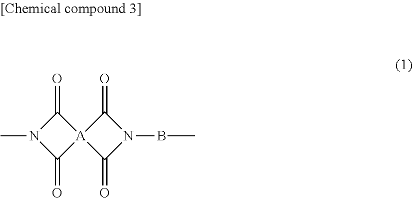

In the chemical formula (1), A denotes a tetravalent tetracarboxylic acid residue containing 2 or more carbon atoms and B denotes a divalent diamine residue containing 2 or more carbon atoms.

Examples of the resin that has a repeating unit as represented by the chemical formula (1) include polyimide resins, polyetherimide resins, and polyamide-imide resins.

A resin film used for this embodiment of the present invention has a light transmittance of 68% or more at a wavelength of 400 nm, and therefore, it can serve suitably to produce a product that requires transparency. The thickness of this resin film is not particularly limited as long as the light transmittance referred to above is 68% or more, but from the viewpoint of the mechanical properties of the resin film, it is preferably 4 μm or more, more preferably 5 μm or more, and still more preferably 6 μm or more. On the other hand, the thickness of this resin film is preferably 40 μm or less, more preferably 30 μm or less, and still more preferably 25 μm or less. If the thickness of the resin film is 4 μm or more and 40 μm or less, the resin film is likely to have good mechanical properties. From the viewpoint of allowing the resin film to have a further improved light transmittance, the film thickness is also preferably 0.5 μm or more and 4 μm or less, and more preferably 1 μm or more and 3 μm or less.

Here, it is particularly preferable for the resin film according to this embodiment of the present invention to have a light transmittance of 68% or more at a wavelength of 400 nm when assuming a thickness of 10 μm. To determine the light transmittance of a resin film assumed to have a thickness of 10 μm, the light transmittance of the resin film having an appropriate thickness is measured and the light transmittance for a thickness of 10 μm is calculated on the assumption that the light transmittance is proportional to the film thickness.

The resin film according to this embodiment of the present invention has a glass transition temperature Tg of 370° C. or more, and accordingly, a layer formed on the resin film is less likely to be creased due to deformation of the resin film in a high temperature process for producing an electronic device. Tg of the resin film is preferably as high as possible because it allows the process for producing an electronic device to be implemented at a higher temperature. For example, Tg is more preferably 380° C. or more.

For the present invention, Tg is measured by using a thermomechanical analysis apparatus. When performing this analysis, a sample is heated to 150° C. at a heating rate of 5° C./min in the first step, and the sample is air-cooled to room temperature at a cooling rate of 5° C./min in the second step, followed by heating the sample at a heating rate of 5° C./min in the third step while taking measurements.

The resin film according to this embodiment of the present invention has a weight loss starting temperature Td₀ of 440° C. or more, and accordingly, a layer formed on the resin film is less likely to suffer peeling, which is also called film lifting, due to gas generation from the resin film in a high temperature process for producing an electronic device. Td₀ of the resin film is preferably as high as possible because it allows the process for producing an electronic device to be implemented at a higher temperature. For example, Td₀ is more preferably 450° C. or more.

For the present invention, Td₀ is measured by using a thermogravimetric analysis apparatus. When performing this analysis, a sample is heated to 150° C. at a heating rate of 10° C./min in the first step, and the sample is air-cooled to room temperature at a cooling rate of 10° C./min in the second step, followed by heating the sample at a heating rate of 10° C./min in the third step while taking measurements.

In the chemical formula (1), A denotes a tetravalent tetracarboxylic acid residue containing 2 or more carbon atoms, wherein the tetracarboxylic acid residue is preferably a tetravalent hydrocarbon group containing 2 to 80 carbon atoms. Here, A may also be a tetravalent organic group containing 2 to 80 carbon atoms that includes hydrogen and carbon as essential components and also includes one or more atoms selected from the group consisting of boron, oxygen, sulfur, nitrogen, phosphorus, silicon, and halogen. In this organic group, the numbers of the boron, oxygen, sulfur, nitrogen, phosphorus, silicon, and halogen atoms contained are each preferably in the range of 20 or less, and more preferably in the range of 10 or less.

There are no specific limitations on the tetracarboxylic acid that gives A, and generally known ones can be used. They include, for example, pyromellitic acid, and 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenonetetracarboxylic acid, 2,2-bis(3,4-dicarboxyphenyl)hexafluoropropane, bis(3,4-dicarboxyphenyl)sulfone, bis(3,4-dicarboxyphenyl)ether, 9,9-bis(3,4-dicarboxyphenyl)fluorene, cyclobutanetetracarboxylic acid, 1,2,3,4-cyclopentanetetracarboxylic acid, and 1,2,4,5-cyclohexanetetracarboxylic acid that have structures as represented by the chemical formula (32), as well as tetracarboxylic acids as specified in International Publication WO 2017/099183. Also included are tetracarboxylic acids that have structures as represented by the chemical formula (33) or structures as represented by the chemical formula (34).

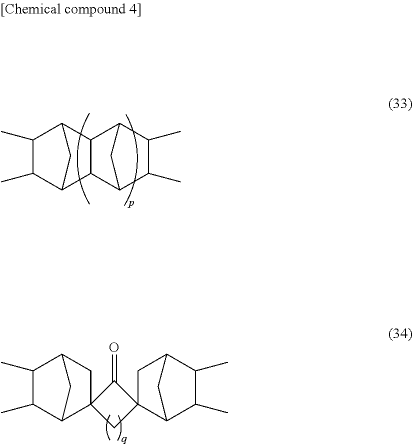

In the chemical formula (33), p denotes an integer of 0 to 3. In the chemical formula (34), q denotes an integer of 1 to 4.

Any of these tetracarboxylic acids may serve as material to give A regardless of whether it is in its original form or in the form of an acid anhydride, active ester, or active amide, and two or more of these may be used in combination.

From the viewpoint of further improving the heat resistance of the resin film, A in the chemical formula (1) is preferably free of a fluorine atom.

From the viewpoint of further improving the heat resistance and transparency of the resin film, A in the chemical formula (1) more preferably contains a structure as represented by the chemical formula (33), a structure as represented by the chemical formula (34), or a 3,3′,4,4′-biphenyltetracarboxylic acid residue as represented by the chemical formula (32), and in particular, the inclusion of a 3,3′,4,4′-biphenyltetracarboxylic acid residue is particularly preferable.

Furthermore, as the tetracarboxylic acid to give A, it may also be good to adopt a silicon-containing tetracarboxylic acid such as dimethylsilane diphthalic acid and 1,3-bis(phthalic acid)tetramethyldisiloxane with the aim of ensuring increased coatability on a support used to form a resin film or increased durability against oxygen plasma treatment or UV ozone treatment performed for cleaning in forming elements on the resin film. When such a silicon-containing tetracarboxylic acid is used, it preferably accounts for 1 to 30 mol % of the total quantity of the tetracarboxylic acids.

For the tetracarboxylic acids given above as examples, part of the hydrogen atoms contained in a tetracarboxylic acid residue may be each replaced with a hydrocarbon group containing 1 to 10 carbon atoms such as methyl group and ethyl group; a fluoroalkyl group containing 1 to 10 carbon atoms such as trifluoromethyl group; or other groups such as F, Cl, Br, and I. In the case where it is to be used to prepare a photosensitive resin composition as described later, part of the hydrogen atoms contained in such a tetracarboxylic acid residue are preferably replaced with acidic groups such as OH, COOH, SO₃H, CONH₂, and SO₂NH₂ because it serves to produce a resin precursor with increased solubility in an aqueous alkali solution.

In the chemical formula (1), B is a divalent diamine residue containing 2 or more carbon atoms, wherein the diamine residue is preferably a divalent hydrocarbon group containing 2 to 80 carbon atoms. Here, B may also be a divalent organic group containing 2 to 80 carbon atoms that includes hydrogen and carbon as essential components and also includes one or more atoms selected from the group consisting of boron, oxygen, sulfur, nitrogen, phosphorus, silicon, and halogen. In this organic group, the numbers of the boron, oxygen, sulfur, nitrogen, phosphorus, silicon, and halogen atoms contained are each preferably in the range of 20 or less, and more preferably in the range of 10 or less.

There are no specific limitations on the diamine that gives B, and generally known ones can be used. They include, for example, m-phenylenediamine, p-phenylenediamine, 2,2′-dimethyl-4,4′-diaminobiphenyl, 2,2′-di(trifluoromethyl)-4,4′-diaminobiphenyl, bis(4-aminophenoxyphenyl) sulfone, 1,4-bis(4-aminophenoxy) benzene, 1,3-bis(3-aminophenoxy) benzene, 1,3-bis(4-aminophenoxy) benzene, bis(3-amino-4-hydroxyphenyl) hexafluoropropane, ethylenediamine, propylenediamine, butanediamine, 1,3-bis(3-aminopropyl) tetramethyldisiloxane, cyclohexanediamine, 4,4′-methylene bis(cyclohexylamine), 9,9-bis(4-aminophenyl) fluorene, and diamines as specified in International Publication No. 2017/099183. Also included are diamines that have structures as represented by the chemical formula (31).

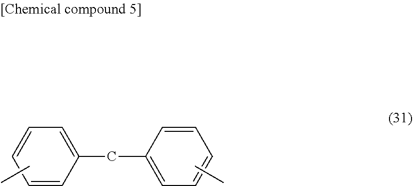

In the chemical formula (31), C denotes an ether group, an ester group, an amide group, or a sulfonyl group.

Examples of a diamine having a structure as represented by the chemical formula (31) include 4,4′-diaminobenzanilide, 3,4′-diaminodiphenyl ether, 4,4′-diaminodiphenyl ether, 3,3′-diaminodiphenyl sulfone, 3,4′-diaminodiphenyl sulfone, 4,4′-diaminodiphenyl sulfone, and 4-aminophenyl 4-aminobenzoate.

Such a diamine may be used in its original form, in the form of a corresponding trimethylsilylated diamine, or in the form of a diamine that gives B.

From the viewpoint of further improving the heat resistance of the resin film, B in the chemical formula (1) is preferably free of a fluorine atom. It is particularly preferable that both A and B are free of a fluorine atom.

From the viewpoint of further improving the heat resistance and transparency of the resin film, B in the chemical formula (1) more preferably has a diamine residue containing a structure as represented by the chemical formula (31), and it is still more preferable to has a 3,3′-diaminodiphenyl sulfone residue or a 4,4′-diaminodiphenyl sulfone residue. It is particularly preferable that A contains a tetracarboxylic acid residue having a structure as represented by the chemical formula (33) or a structure as represented by the chemical formula (34) or contains a 3,3′,4,4′-biphenyltetracarboxylic acid residue while B contains a diamine residue having a structure as represented by the chemical formula (31). Most preferably, A has a 3,3′,4,4′-biphenyltetracarboxylic acid residue and B has a 3,3′-diaminodiphenyl sulfone residue or a 4,4′-diaminodiphenyl sulfone residue.

If A and B have these structures, it will be easy to produce a resin film having high heat resistance and transparency.

As a diamine to give B, furthermore, it may be good to use a silicon-containing diamine such as 1,3-bis(3-aminopropyl)tetramethyl disiloxane and 1,3-bis(4-anilino)tetramethyl disiloxane with the aim of ensuring increased coatability on a support used to form a resin film or increased durability against oxygen plasma treatment or UV ozone treatment performed for cleaning in forming elements on the resin film. It is preferable that these silicon-containing diamine compounds account for 1 to 30 mol % of the total quantity of diamine compounds.

For the diamine compounds given above as examples, part of the hydrogen atoms contained in a diamine compound may each be replaced with a hydrocarbon group containing 1 to 10 carbon atoms such as methyl group and ethyl group; a fluoroalkyl group containing 1 to 10 carbon atoms such as trifluoromethyl group; or other groups such as F, Cl, Br, and I. In the case where it is to be used to prepare a photosensitive resin composition as described later, part of the hydrogen atoms contained in such a diamine compound are preferably replaced with an acid group such as OH, COOH, SO₃H, CONH₂, and SO₂NH₂ because it serves to produce a resin precursor with increased solubility in an aqueous alkali solution.

The value calculated by dividing the number of moles of diamine residues contained in the resin by the number of moles of tetracarboxylic acid residues (hereinafter referred to as quotient Ka) is not particularly limited, but it is preferably 0.4 or more, and more preferably 0.6 or more. On the other hand, the quotient Ka is preferably 0.95 or less, more preferably 0.9 or less, and still more preferably 0.8 or less. If the quotient Ka is 0.4 or more, it serves to produce a resin film having good mechanical properties. A quotient Ka of 0.95 or less is preferable because it allows the resin to include a larger number of structures as represented by the chemical formula (2) described later.

Here, as the quotient Ka comes closer to 1, the number of moles of diamine residues comes closer to the number of moles of tetracarboxylic acid residues and the number of repetition of the repeating unit represented by the chemical formula (1) is likely to increase. In addition, the polymer structure having a repeating unit as represented by the chemical formula (1) tends to have tetracarboxylic acid groups at the chain ends if the quotient Ka is smaller than 1, whereas the polymer structure having a repeating unit as represented by the chemical formula (1) tends to have diamine groups at the chain ends if it is larger than 1.

It is preferable for the above resin to have a structure as represented by the chemical formula (2).

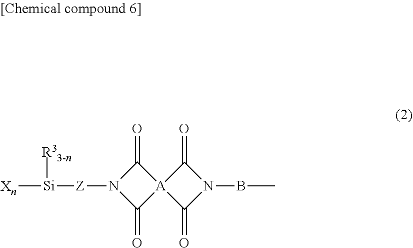

In the chemical formula (2), A denotes a tetravalent tetracarboxylic acid residue containing 2 or more carbon atoms and B denotes a divalent diamine residue containing 2 or more carbon atoms. Z denotes an aminosilane residue containing 1 to 10 carbon atoms. R³ denotes a hydrocarbon group containing 1 to 20 carbon atoms. In addition, n denotes 2 or 3. X denotes a structure as represented by the chemical formula (3), and the oxygen atom in the chemical formula (3) is bonded to the Si atom in the chemical formula (2).

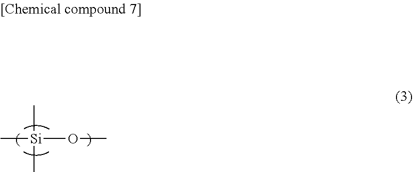

A resin film containing a resin having a structure as represented by the chemical formula (2) tends to be suitably high in light transmittance, Tg, and Td₀. The structure represented by the chemical formula (2) defines the terminal structure of the resin that has a repeating unit as represented by the chemical formula (1). In the case where the chain end of the above resin is a tetracarboxylic acid located at the end of a repeating unit as represented by the chemical formula (1), it is considered that an aminosilane compound having a siloxane structure is imide-bonded to the tetracarboxylic acid structure located at the chain end. Since the siloxane bonding site is high in heat resistance and light transmittance, the resin film is high in light transmittance and Td₀. In a resin having a structure as represented by the chemical formula (2), furthermore, the chain ends of the polymer structure having a repeating unit as represented by the chemical formula (1) are immobilized by siloxane bonds, and it is inferred that this acts to limit the thermal motion of the resin to allow the resin film to have a higher Tg.

In the chemical formula (2), Z denotes an aminosilane residue containing 1 to 10 carbon atoms, and examples of Z include aliphatic hydrocarbon groups each containing 1 to 10 carbon atoms and aromatic hydrocarbon groups each containing 6 to 10 carbon atoms. These hydrocarbon groups may have any of straight-chain, branched, and cyclic structures. From the viewpoint of further improving the heat resistance of the resin film, Z is preferably an aromatic hydrocarbon group containing 6 to 10 carbon atoms and more preferably a phenyl group.

In the chemical formula (2), R³ denotes a hydrocarbon group containing 1 to 20 carbon atoms, and examples of R³ include aliphatic hydrocarbon groups each containing 1 to 20 carbon atoms and aromatic hydrocarbon groups each containing 6 to 20 carbon atoms. These hydrocarbon groups may have any of straight-chain, branched, and cyclic structures. From the viewpoint of further improving the heat resistance of the resin film, R³ is preferably an aliphatic hydrocarbon group containing 1 or 2 carbon atoms or an aromatic hydrocarbon group containing 6 to 20 carbon atoms, and more preferably a methyl group or a phenyl group.

In the chemical formula (2), n denotes an integer of 2 or 3, and it is preferably 3. When n is 3, the siloxane bonding site has a three-dimensional structure, possibly allowing the resin film to have a further increased Tg.

The value calculated by dividing the number of moles of aminosilane residues contained in the resin by the number of moles of tetracarboxylic acid residues (hereinafter referred to as quotient Kb) is preferably 0.1 or more, more preferably 0.2 or more, and still more preferably 0.4 or more. On the other hand, the quotient Kb is preferably 1.2 or less, and more preferably 0.9 or less. When the quotient Kb is 0.1 or more, the resin contains a larger number of structures as represented by the chemical formula (2), accordingly serving to form a resin film higher in transparency and heat resistance. If the quotient Kb is 1.2 or less, it serves to form a resin film having good mechanical properties.

In the chemical formula (2), X denotes a structure as represented by the chemical formula (3), and the oxygen atom in the chemical formula (3) is bonded to the Si atom in the chemical formula (2). Examples of the site that bonds to the Si atom in the chemical formula (3) include a carbon atom contained in R³ in the chemical formula (2) and a carbon atom contained in Z in the chemical formula (2), hydrogen atom, and hydroxyl group.

Furthermore, the Si atom in the chemical formula (3) may bond via an oxygen atom to Si atom in another chain of the polymer represented by the chemical formula (2) or (3) to form repeated chain-like or net-like siloxane structures. The Si atom in the chemical formula (3) may be the Si atom in another chain of the polymer represented by the chemical formula (2) or part of the Si atoms in repeating units as represented by chemical formula (3) may be the Si atom in another chain of the polymer represented by the chemical formula (2). A structure in which the Si atom in the chemical formula (3) coincides with the Si atom in another chain of the polymer represented by the chemical formula (2) is preferable because the structure can be considered to be formed of different resins each having a structure as represented by the chemical formula (2) that are crosslinked through siloxane structures, thus leading to a resin film having a higher Tg.

### <Resin Composition>

The resin composition according to the embodiment of the present invention is a resin composition that contains a resin having a repeating unit as represented by the chemical formula (4) and a solvent and is characterized by serving to form, when being spread and baked at 410° C., a 10 μm thick resin film having a light transmittance of 68% or more at a wavelength of 400 nm, a glass transition temperature of 370° C. or more, and a weight loss starting temperature of 440° C. or more. Here, baking at 410° C. means baking at 410° C. for 30 minutes. Characteristics of a 10 μm thick resin film formed by baking at 410° C. are specified here because heating at 410° C. or more is commonly required in producing a resin film having a heat resistance high enough to withstand high-temperature processes used for the manufacture of electronic devices. In regard to the thickness of 10 μm, it is because films having thickness of about 10 μm are mainly used in producing products that require good mechanical properties (display substrates, for example).

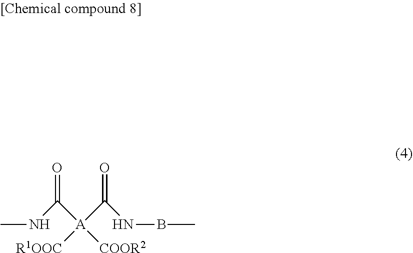

In the chemical formula (4), A denotes a tetravalent tetracarboxylic acid residue containing 2 or more carbon atoms and B denotes a divalent diamine residue containing 2 or more carbon atoms. R¹ and R² each independently denote a hydrogen atom, a hydrocarbon group containing 1 to 10 carbon atoms, an alkyl silyl group containing 1 to 10 carbon atoms, an alkali metal ion, an ammonium ion, an imidazolium ion, or a pyridinium ion.

The resin composition according to the embodiment of the present invention serves to form a resin film having a light transmittance of 68% or more, and therefore, the resin composition can be used suitably to produce a product that requires transparency.

Furthermore, the resin composition according to the embodiment of the present invention serves to form a resin film having a Tg of 370° C. or more, and in high-temperature processes used for the manufacture of electronic devices, therefore, layers formed on the resin film are less likely to suffer creasing. Thus, it can be suitably used in electronic devices that have to pass through high-temperature processes during manufacturing. In addition, the Tg of the resin film is preferably as high as possible because it allows the process for producing an electronic device to be implemented at a higher temperature. For example, it is more preferable for the resulting resin film to have a Tg of 380° C. or more.

Furthermore, the resin composition according to the embodiment of the present invention serves to form a resin film having a Td₀ of 440° C. or more, and in high-temperature processes used for the manufacture of electronic devices, therefore, layers formed on the resin film are less likely to suffer peeling, i.e. film lifting. Thus, it can be suitably used in electronic devices that have to pass through high-temperature processes during manufacturing. In addition, Td₀ of the resin film is preferably as high as possible because it allows the process for producing an electronic device to be implemented at a higher temperature. For example, it is more preferable for the resulting resin film to have a Td₀ of 450° C. or more.

Any resin having a repeating unit as represented by the chemical formula (4) can be converted into a resin having a repeating unit as represented by the chemical formula (1) by subjecting it to heat treatment, chemical treatment, or the like. Thus, a resin having a repeating unit as represented by the chemical formula (4) and a resin having a repeating unit as represented by the chemical formula (5) described below are hereinafter referred to as precursor resins. In addition, a resin composition containing a precursor resin is referred to as a precursor resin composition. Examples of precursor resins include polyimide precursor resins, polyetherimide precursor resins, and polyamide-imide precursor resins.

Specific and preferred examples of A in the chemical formula (4) include the structures described above as specific and preferred examples of A in the chemical formula (1). Specific and preferred examples of B in the chemical formula (4) include the structures described above as specific and preferred examples of B in the chemical formula (1).

Furthermore, the value calculated by dividing the number of moles of diamine residues contained in the precursor resin by the number of moles of tetracarboxylic acid residues (hereinafter referred to as quotient Kc) is preferably 0.4 or more, and more preferably 0.6 or more. On the other hand, the quotient Kc is preferably 0.9 or less, and more preferably 0.8 or less. If the quotient Kc is 0.4 or more, it serves to produce a resin film having good mechanical properties. A quotient Kc of 0.9 or less is preferable because it allows the resin to include a larger number of structures as represented by the chemical formula (5) described below.

It is also preferable for the above precursor resin to have a structure as represented by the chemical formula (5).

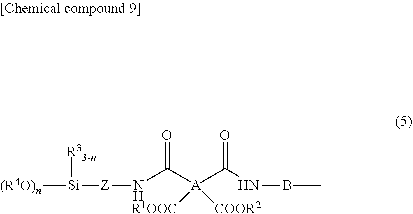

In the chemical formula (5), A denotes a tetravalent tetracarboxylic acid residue containing 2 or more carbon atoms and B denotes a divalent diamine residue containing 2 or more carbon atoms. R¹ and R² each independently denote a hydrogen atom, a hydrocarbon group containing 1 to 10 carbon atoms, an alkyl silyl group containing 1 to 10 carbon atoms, an alkali metal ion, an ammonium ion, an imidazolium ion, or a pyridinium ion. R³ and R⁴ each independently represent a hydrocarbon group containing 1 to 20 carbon atoms. In addition, n denotes 2 or 3.

If a precursor resin composition containing a precursor resin having a structure as represented by the chemical formula (5) is adopted, a 10 μm thick resin film that is higher in light transmittance, Tg, and Td₀ can be produced easily by spreading the resin composition and baking it at 410° C. In the case of a precursor resin having a structure as represented by the chemical formula (5) in which the end group of the precursor resin is a tetracarboxylic acid group as in the repeating unit represented by the chemical formula (4), its structure is deemed to be formed in such a manner that an aminosilane compound having a hydrolyzable silyl group is bonded to the tetracarboxylic acid structure at the above chain end to form an amic acid. The amic acid structure is converted into an imide structure by baking, and the hydrolyzable silyl group is converted into a siloxane structure by baking. This means that a structure as represented by the chemical formula (5) can be converted by heating into a structure as represented by the chemical formula (2). Accordingly, a resin film produced by baking a precursor resin composition containing a precursor resin having a structure as represented by the chemical formula (5) contains a resin having a structure as represented by the chemical formula (2), and it is considered that because of this, a resin film produced by baking it has further increased light transmittance, Tg, and Td₀.

Specific and preferred examples of Z in the chemical formula (5) include the structures described above as specific and preferred examples of Z in the chemical formula (2).

Specific and preferred examples of R³ in the chemical formula (5) include the structures described above as specific and preferred examples of R³ in the chemical formula (2).

For the chemical formula (5), examples of R⁴ include aliphatic hydrocarbon groups each containing 1 to 20 carbon atoms and aromatic hydrocarbon groups each containing 6 to 20 carbon atoms. These hydrocarbon groups may have any of straight-chain, branched, and cyclic structures.

In the chemical formula (5), n denotes an integer of 2 or 3, and it is preferably 3. When n is 3, the siloxane bonding site in the baked resin has a three-dimensional structure, possibly allowing the resin film to have a further increased Tg.

Examples of an aminosilane compound giving the chemical formula (5) include 4-aminophenyl trimethoxysilane, 4-aminophenyl triethoxysilane, 4-aminophenylmethyl dimethoxysilane, 4-aminophenylmethyl diethoxysilane, 3-aminophenyl trimethoxysilane, 3-aminophenyl triethoxysilane, 3-aminophenylmethyl dimethoxysilane, 3-aminophenylmethyl diethoxysilane, 2-aminophenyl trimethoxysilane, 2-aminophenyl triethoxysilane, 2-aminophenylmethyl dimethoxysilane, 2-aminophenylmethyl diethoxysilane, 3-aminopropyl trimethoxysilane, 3-aminopropyl triethoxysilane, 3-aminopropylmethyl dimethoxysilane, and 3-aminopropylmethyl diethoxysilane. In particular, it is preferable to adopt an aminosilane compound selected from the group consisting of 3-aminophenyl trimethoxysilane, 3-aminophenyl triethoxysilane, 4-aminophenyl trimethoxysilane, and 4-aminophenyl triethoxysilane.

The value calculated by dividing the number of moles of aminosilane residues contained in the precursor resin by the number of moles of tetracarboxylic acid residues (hereinafter referred to as quotient Kd) is preferably 0.1 or more, more preferably 0.2 or more, and still more preferably 0.4 or more. On the other hand, the quotient Kd is preferably 1.2 or less, and more preferably 0.9 or less. When the quotient Kd is 0.1 or more, the precursor resin contains a larger number of structures as represented by the chemical formula (5), accordingly serving to form a resin film higher in transparency and heat resistance. If the quotient Kd is 1.2 or less, it serves to produce a resin film having good mechanical properties.

For the present invention, the precursor resin may further contain, in addition to a repeating unit as represented by the chemical formula (4), at least one selected from the group consisting of the repeating units represented by the chemical formula (61), repeating units represented by the chemical formula (62), and repeating units represented by the chemical formula (1).

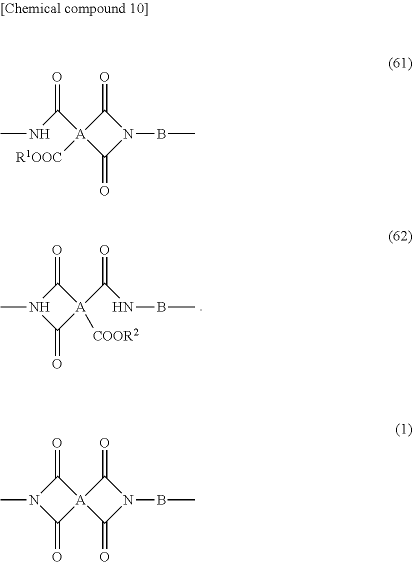

In the chemical formulae (61), (62), and (1) given above, A, B, R¹, and R² are the same as described above. Each of the repeating units represented by the chemical formula (61), repeating units represented by the chemical formula (62), and repeating units represented by the chemical formula (1) is a structure that can be produced by subjecting a repeating unit as represented by the chemical formula (4) to heat treatment, chemical treatment, or the like to cause imide ring closure. This means that a precursor resin that contains a repeating unit as represented by the chemical formula (4) and at least one selected from the group consisting of the repeating units represented by the chemical formula (61), repeating units represented by the chemical formula (62), and repeating units represented by the chemical formula (1) can be regarded as a partially imidized precursor resin.

Here, the molar ratios of the repeating unit represented by the chemical formula (4), repeating unit represented by the chemical formula (61), repeating unit represented by the chemical formula (62), and repeating unit represented by the chemical formula (1) contained in a precursor resin are referred to s, t, u, and v, respectively. Then, the imidization rate of a polyimide precursor is a value calculated by the following equation: (t+u+2v)/(2s+2t+2u+2v)×100. Thus, the imidization rate shows the proportion of the number of imide ring-closed bonds, which is equal to t+u+2v, to the total number of bonds, which is equal to 2s+2t+2u+2v, in the bonding sites (reaction sites between the tetracarboxylic dianhydride and diamine compound involved) in a polyimide precursor.

From the viewpoint of improving the storage stability of the precursor resin composition, the imidization rate of the precursor resin is preferably 5 to 30%. The imidization rate is more preferably 10% or more, and still more preferably 13% or more. On the other hand, it is more preferably 27% or less, and still more preferably 25% or less.

The imidization rate of a precursor resin is measured as follows. First, ¹H-NMR spectra of the precursor resin are observed. The integrated peak area of ¹H in the amide group (referred to as E) is measured. Then, it is assumed that the molar ratio among the repeating units represented by the chemical formula (4), those represented by the chemical formula (61) or the chemical formula (62), and those represented by the chemical formula (1) existing in the precursor resin is 100:0:0, and the integrated peak area of ¹H in the amide group in that case (referred to as 3) is determined. In other words, the integrated peak area of ¹H in the amide group is calculated on the assumption that the precursor resin is in the form of the basic amic acid resin that is not imidized. From these β and ε values, the imidization rate can be calculated by the following equation.

Imidization rate=(β−ε)/β×100

Here, β can be calculated by the following equation. In the following equation, α denotes the integrated peak area of all ¹H atoms or specific ¹H atoms contained in A and B in the chemical formula (4), chemical formula (61), chemical formula (62), and chemical formula (1). In addition, w is the number of hydrogen atoms involved in calculating the α value.

β=α/ω×2

A sample used for ¹H-NMR measurement is preferably a pure precursor resin, but may contain another resin component or a solvent. It is preferable, however, that the peak of ¹H contained in such another component should not overlap the peak of ¹H that is involved in calculating the imidization rate.

There are no specific limitations on the solvent contained in the precursor resin composition as long as it can dissolve the precursor resin. Examples of such a solvent include aprotic polar solvents such as N-methyl-2-pyrrolidone, γ-butyrolactone, N,N-dimethyl formamide, N,N-dimethyl acetamide, 3-methoxy-N,N-dimethyl propionamide, 3-butoxy-N,N-dimethyl propionamide, N,N-dimethylisobutyl amide, 1,3-dimethyl-2-imidazolidinone, N,N′-dimethylpropylene urea, and dimethyl sulfoxide; ethers such as tetrahydrofuran, dioxane, propylene glycol monomethyl ether, propylene glycol monoethyl ether, diethylene glycol monomethyl ether, diethylene glycol monoethyl ether, diethylene glycol ethylmethyl ether, and diethylene glycol dimethyl ether; ketones such as acetone, methyl ethyl ketone, diisobutyl ketone, diacetone alcohol, and cyclohexanone; esters such as ethyl acetate, propylene glycol monomethyl ether acetate, ethyl lactate, 3-methyl-3-methoxybutyl acetate, ethylene glycol ethyl ether acetate, and 3-methoxybutyl acetate; aromatic hydrocarbons such as toluene and xylene; and solvents as specified in International Publication WO 2017/099183. As the aforementioned solvent, one of these may be used singly, or two or more of these may be used in combination.

The precursor resin composition may contain a silane compound (h). It is preferable for the silane compound (h) to be a compound having a structure as represented by the chemical formula (7).

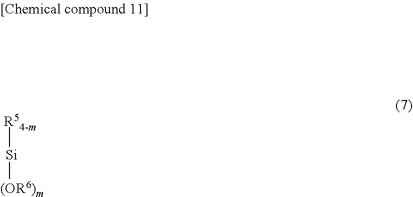

In the chemical formula (7), R⁵ and R⁶ each independently denote a hydrocarbon group containing 1 to 20 carbon atoms. In addition, m denotes 3 or 4.

If the precursor resin composition contains a silane compound (h), the silane compound (h) condenses to form siloxane bonds during baking of the precursor resin composition. Consequently, siloxane sites are formed in the resin film produced by baking, thereby leading to a resin film having a further improved light transmittance. In particular, in the case where the precursor resin composition contains a precursor resin having a structure as represented by the chemical formula (5), the silane compound (h) and the hydrolysable silyl group in the chemical formula (5) will undergo condensation to form a siloxane bond during the baking step, which acts to suppress the phase separation between the resin and the siloxane sites in the resin film, leading to easy formation of a resin film having a high light transmittance.

For example, R⁵ in the chemical formula (7) may be an aliphatic hydrocarbon group containing 1 to 20 carbon atoms or an aromatic hydrocarbon group containing 6 to 20 carbon atoms. These hydrocarbon groups may have any of straight-chain, branched, and cyclic structures. From the viewpoint of further improving the heat resistance of the resin film, R⁵ is preferably an aliphatic hydrocarbon group containing 1 or 2 carbon atoms or an aromatic hydrocarbon group containing 6 to 20 carbon atoms, more preferably a methyl group or a phenyl group, and particularly preferably a phenyl group.

For the chemical formula (7), examples of R⁶ include aliphatic hydrocarbon groups each containing 1 to 20 carbon atoms and aromatic hydrocarbon groups each containing 6 to 20 carbon atoms. These hydrocarbon groups may have any of straight-chain, branched, and cyclic structures.

Examples of a compound having a structure as represented by the chemical formula (7) include tetramethoxysilane, tetraethoxysilane, tetrapropoxysilane, tetrabutoxysilane, tetraphenoxysilane, methyltrimethoxysilane, methyltriethoxysilane, ethyltrimethoxysilane, ethyltriethoxysilane, phenyltrimethoxysilane, and phenyltriethoxysilane.

The silane compound (h) preferably accounts for 15 parts by mass or more and 100 parts by mass or less relative to 100 parts by mass of the precursor resin composition. If the silane compound (h) preferably accounts for 15 parts by mass or more, it serves for easy production of a resin film having a further improved light transmittance. If it is 100 parts by mass or less, it serves for easy production of a resin film having good mechanical characteristics.

In addition, the precursor resin composition may contain, as required, at least one additive selected from the following: photoacid generation agent (a), heat crosslinking agent (b), thermal acid generating agent (c), compound containing a phenolic hydroxy group (d), adhesion improving agent (e), surface active agent (f), and inorganic particle (g). Specific examples of these additives include those specified in International Publication WO 2017/099183.

In the precursor resin composition, the precursor resin preferably accounts for 3 mass % or more, and more preferably 5 mass % or more, relative to 100 mass % of the precursor resin composition. Furthermore, it preferably accounts for 50 mass % or less, and more preferably 40 mass % or less.

The precursor resin composition preferably has a viscosity of 20 to 20,000 mPa·s, and more preferably 50 to 10,000 mPa·s.

### <Production Method for Precursor Resin Composition>

Next, the method for producing a precursor resin composition is described below. In the method for producing a precursor resin composition, a precursor resin is dissolved or dispersed in a solvent together with a silane compound (h), photoacid generation agent (a), heat crosslinking agent (b), thermal acid generating agent (c), compound containing a phenolic hydroxy group (d), adhesion improving agent (e), surface active agent (f), or an inorganic particle (g), as required. As a result, a precursor resin composition can be prepared in the form of a varnish.

Here, a precursor resin having a repeating unit as represented by the chemical formula (4) can be polymerized by a known method. For example, it can be produced by polymerizing an acid component such as tetracarboxylic acid, a corresponding acid dianhydride, active ester, and active amide with a diamine component such as diamine and a corresponding trimethylsilylated diamine in a reaction solvent. Here, the precursor resin may be in the form of a salt formed through a reaction of the carboxyl group with an alkali metal ion, ammonium ion, or imidazolium ion, or may be in the form of an ester formed through esterification with a hydrocarbon group containing 1 to 10 carbon atoms or an alkyl silyl group containing 1 to 10 carbon atoms.

Useful reaction solvents include, for example, those listed above as specific examples of solvents to include in the precursor resin composition. They may be used singly or two or more thereof may be used as a mixture. It is preferable for the quantity of the reaction solvent to be adjusted so that the tetracarboxylic acid and diamine compound altogether account for 0.1 to 50 mass % of the total quantity of the reaction solution. In addition, the reaction temperature is preferably −20° C. to 150° C., and more preferably 0° C. to 100° C. The reaction time, furthermore, is preferably 0.1 to 24 hours, and more preferably 0.5 to 12 hours.

Here, a precursor resin having a structure as represented by the chemical formula (5) can be produced by methods as described below.

### Production Method 1:

The first production method includes a first step for reacting a tetracarboxylic dianhydride and an aminosilane compound to produce a compound as represented by the chemical formula (9) and a second step for reacting the compound represented by the chemical formula (9) with a diamine compound and a tetracarboxylic dianhydride to produce a precursor resin having a structure as represented by the chemical formula (5).

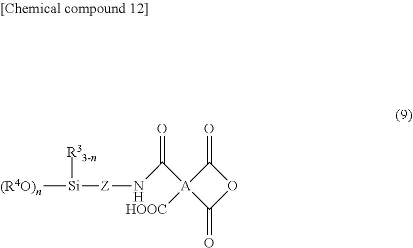

In the chemical formula (9), A denotes a tetravalent tetracarboxylic acid residue containing 2 or more carbon atoms. R³ and R⁴ each independently represent a hydrocarbon group containing 1 to 20 carbon atoms. In addition, n denotes 2 or 3.

### Production Method 2:

The second production method includes a first step for reacting a diamine compound and a tetracarboxylic dianhydride to produce a precursor resin having a repeating unit as represented by the chemical formula (4) and a second step for reacting a resin having a structure as represented by the chemical formula (10) and an aminosilane compound to produce a precursor resin having a structure as represented by the chemical formula (5).

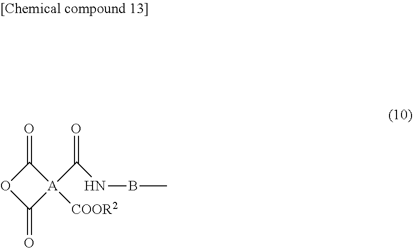

In the chemical formula (10), A denotes a tetravalent tetracarboxylic acid residue containing 2 or more carbon atoms and B denotes a divalent diamine residue containing 2 or more carbon atoms. R² denotes a hydrogen atom, a hydrocarbon group containing 1 to 10 carbon atoms, an alkyl silyl group containing 1 to 10 carbon atoms, an alkali metal ion, an ammonium ion, an imidazolium ion, or a pyridinium ion.

Here, the production methods 1 and 2 may be used in combination to produce a precursor resin having a structure as represented by the chemical formula (5).

It is noted that in the above production methods, the tetracarboxylic acid may be in the form of a corresponding acid dianhydride, active ester, or active amide. The diamine compound, furthermore, may be in the form of a corresponding trimethyl silylated diamine. In addition, the resulting resin may be in the form of a salt formed through a reaction of the carboxyl group with an alkali metal ion, ammonium ion, or imidazolium ion or may be in the form of an ester formed through esterification with a hydrocarbon group containing 1 to 10 carbon atoms or an alkyl silyl group containing 1 to 10 carbon atoms.

The resulting precursor resin solution may be used as-obtained as precursor resin composition for the embodiment of the present invention. In that case, the same solvent as the one to be used to prepare a precursor resin composition may be adopted as the reaction solvent or a solvent may be added after the completion of the reaction in order to produce the intended precursor resin composition without isolating the precursor resin.

Furthermore, the resulting precursor resin may be modified by imidizing or esterifying part of the repeating unit of the amic acid. In that case, the precursor resin solution resulting from the polymerization of a precursor resin may be applied directly to the next reaction, or the precursor resin may be isolated for use in the next reaction.

For the esterification and imidization of the precursor resin as well, the same solvent as the one to be used to prepare a precursor resin composition may be adopted as the reaction solvent or a solvent may be added after the completion of the reaction in order to produce the intended precursor resin composition without isolating the precursor resin.

### (Production Method for Resin Film)

Next, a production method for a resin film according the embodiment of the present invention is described below. This production method for a resin film is given here as a typical method for producing a resin film according to the embodiment of the present invention from the aforementioned precursor resin composition.

First, a varnish is prepared as a precursor resin composition according to the embodiment of the present invention and spread over a support. Good examples of such a support include wafer substrates of silicon, gallium arsenide, or the like; glass substrates of sapphire glass, soda lime glass, alkali-free glass, or the like; metal substrates of stainless steel, copper, or the like; and others such as metal foil and ceramic substrate. Of these, alkali-free glass is preferable from the viewpoint of surface smoothness and dimensional stability during heating.

Useful varnish coating methods include spin coating, slit coating, dip coating, spray coating, and printing, which may be used in combination. When producing a resin film to be used as a substrate for a display device, it will be necessary to spread the varnish over a support with a large size and accordingly, the use of the slit coating method is preferred.

The coating step is commonly followed by drying the varnish coating film. Useful drying methods include reduced pressure drying, thermal drying, and combinations thereof. For example, a typical procedure for reduced pressure drying is to form a coating film on a support, place it in a vacuum chamber, and reduce the pressure in the vacuum chamber to dry the coating film. Here, good drying methods include the use of a hot plate, oven, infrared ray, or the like that serve to dry the coating film. When using a hot plate, a coating film is put directly on a plate or a coating film is formed on a support, followed by mounting it on a jig such as proxy pin fixed on a plate, so that the coating film is dried thermally. Depending on the type of solvent used in the varnish and the purpose thereof, heating is performed preferably at a temperature in the range from room temperature to 180° C. for 1 minute to several hours.

When the resin composition used for coating contains a photoacid generating agent (a), a pattern can be formed from the dried coating film by the process described below. For example, this process includes light exposure that is performed by applying an actinic ray to the coating film through a mask having an intended pattern. Various actinic rays available for light exposure include ultraviolet ray, visible light, electron beam, and X-ray, but the i-line (365 nm), h-line (405 nm), and g-line (436 nm) of mercury lamps are preferred for the present invention. When the coating film is positively photosensitive, the exposed regions in the coating film are dissolved in a developer. When the coating film is negatively photosensitive, the exposed regions in the coating film are hardened and become insoluble in a developer.

After the light exposure, a developer is used to remove the exposed regions from a positively photosensitive film or remove the unexposed regions from a negatively photosensitive film to form an intended pattern on the coating film. As the developer, the use of an aqueous solution of an alkaline compound such as tetramethylammonium is preferable regardless of whether the film is of a positive type or a negative type. In some cases, furthermore, such an alkali solution may contain polar solvents such as N-methyl-2-pyrrolidone and others such as alcohols, esters, and ketones, which may be added singly or in combination.

Subsequently, a heating step is performed to heat-treat the coating film on the support to produce a resin film. In this heating step, the coating film is heat-treated at a temperature of 370° C. to 600° C., preferably 400° C. to 490° C., more preferably 410° C. to 470° C. to bake the coating film. This serves to form a resin film on the support. If the heating temperature (baking temperature) used for the coating film in the heating step is 370° C. or more, its imidization proceeds sufficiently, and a resin film having good mechanical properties can be produced. If the heating temperature is 400° C. or more, it serves to produce a resin film that is high in heat resistance. On the other hand, if the heating temperature is 490° C. or less, thermal decomposition of the resin is suppressed, and a resin film with a high transmittance can be produced.

A resin film produced through such steps for coating and heating as described above can be used after peeling it from the support or can be used together with the support without peeling it therefrom.

Useful peeling techniques include mechanical peeling, immersion in water, immersion in a chemical solution such as hydrochloric acid and hydrofluoric acid, and application of a laser beam in the wavelength range from ultraviolet to infrared to the interface between the resin film and the support. When the resin film is peeled after a device is formed thereon, in particular, it is necessary to perform its peeling without damaging the device, and therefore, it is preferable to peel it using an ultraviolet laser.

Here, in order to ensure easy peeling, a mold releasing agent may be spread or a sacrifice layer may be formed over the support before spreading the resin composition over the support. Useful mold releasing agents include silicone based, fluorine based, aromatic polymer based, and alkoxysilane based ones. Useful sacrifice layers include metal film, metal oxide film, and amorphous silicon film.

The resin film according to the embodiment of the present invention can be suitably used for display substrates such as organic EL display substrates, color filter substrates, touch panel substrates, electronic paper substrates, and μLED display substrates, and is particularly suitable for flexible display substrates. It can also be applied to flexible printed boards, solar battery substrates, surface protect film and interlayer insulation film of semiconductor elements, insulation layers and spacer layers of organic electroluminescent elements (organic EL elements), planarizing film of thin film transistor substrates, insulation layers of organic transistors, binders for electrodes of lithium ion secondary batteries, and adhesives for semiconductors.

### (Display)

Next, the display according to an embodiment of the invention is described below. The display according to the embodiment of the present invention contains a resin film according to an embodiment of the present invention.

A production method for a display according to an embodiment of the present invention is described below.

It is a typical display according to an embodiment of the present invention and it includes a resin film and a display element formed on the resin film.

The resin film is a resin film according to an embodiment of the present invention and can function as a substrate for a display. The resin film has a display element formed thereon.

This method for producing a display includes a film production step for producing a resin film on a support by the production method for a resin film described above, a step of forming a display element on the resin film, and a peeling step for peeling the resin film from the support.

First, a resin film according to an embodiment of the present invention is produced on a support by the production method for a resin film described above.

An inorganic film may be provided on the resin film if required. If an inorganic film is provided, it can serve to prevent external moisture and oxygen from passing through the resin film to cause deterioration of the display element. Good materials for such an inorganic film include silicon oxide (SiOx), silicon nitride (SiNy), and silicon oxynitride (SiOxNy). These may be in the form of a monolayer or a plurality of stacked layers. To produce such inorganic films, it is preferable to use a deposition method such as the chemical vapor deposition (CVD) technique and the physical vapor deposition (PVD) technique. These inorganic films may be combined with resin films to form a stack of a plurality of alternate resin films and inorganic films. The resin films used in combination with the inorganic films are preferably resin films according to an embodiment of the present invention. It is also good to form a different type resin film on a support, followed by forming inorganic films and resin films according to an embodiment of the present invention alternately on the resin film.

Subsequently, a display element suitable for the intended display is formed on the resulting resin film or stack of resin films and inorganic films. When the display is an organic EL display, for example, an organic EL element is formed as the intended display element by forming a TFT as display element, a first electrode, a light emitting element, a second electrode, and a sealing film in this order. When the display is a liquid crystal display, a liquid crystal display element is produced as the intended display element by forming a liquid crystal cell using a TFT as image driving element, a first electrode, a first substrate having a first oriented film formed thereon, a second electrode, and a second substrate having a second oriented film formed thereon, followed by injecting a liquid therein. When the display is a display including a color filter, a color filter element is produced as the intended display element by forming a black matrix as required and then forming color pixels of red, green, and blue. When the display is a display including a touch panel, a touch panel element is formed as the target display element by forming a wiring layer and an insulation layer.

Finally, the resin film is peeled from the support, and a display containing a resin film according to the present invention can be produced by using the peeled resin film (having an intended display element formed thereon). The peeling along the interface between the support and the resin film is carried out by using an appropriate technique such as the use of a laser, mechanical peeling, and etching of the support. When using a laser, a laser beam is preferably applied to the element-free surface of the support such as glass substrate in order to allow the resin film to be peeled without causing damage to the element. To facilitate the peeling, furthermore, a primer layer may be provided between the support and the resin film.

### EXAMPLES

The present invention will be illustrated below in greater detail with reference to examples etc., but it should be understood that the invention is not limited to these examples etc. First, the procedures for measurement, evaluation, test, etc. performed in the examples and comparative examples given below will be described. It is noted that only one measurement is taken (n=1) unless otherwise specified.

### (Item 1: Measurement of Viscosity Change Rate of Precursor Resin Composition)

The resin composition (varnish) prepared in each Synthesis example was stored in a Clean Bottle (manufactured by Aicello Corporation) at 23° C. for 10 days. The viscosity of the resin composition (varnish) was measured before and after the storage, and the viscosity change rate was calculated by the equation given below. Here, the viscosity was measured at 25° C. using a viscometer (TVE-22H, manufactured by Toki Sangyo Co., Ltd.).

Viscosity change rate (%)=(viscosity after storage−viscosity before storage)/viscosity before storage×100

### (Item 2: Measurement of an Imidization Rate of Precursor Resin)

For the precursor resin prepared in each Synthesis example, the ¹H-NMR spectrum was observed using a magnetic nuclear resonance apparatus (EX-270, manufactured by JEOL Ltd.). The resin composition (varnish) prepared in each Synthesis example was diluted with a deuterated solvent (deuterated dimethylsulfoxide) to provide a specimen for measurement. Then, the total integrated area of all ¹H peaks (referred to as a) from the diamine residue and tetracarboxylic acid residue components in the precursor resin composition was determined. Then, the integrated area of the H peak (referred to as E) from the amide group in the precursor resin was determined. Using these values, the imidization rate of the precursor resin contained in the components of the precursor resin composition was measured.

Imidization rate=(β−ε)/β×100

Here, β=α/ω×2, and w is the number of hydrogen atoms involved in calculating the α value.

### (Item 3: Measurement of Light Transmittance of Resin Film)

For the resin film prepared in each Example, a stack of a resin film layer and a glass substrate was produced, and the resulting stack was examined using an ultraviolet-visible spectrophotometer (MultiSpec 1500, manufactured by Shimadzu Corporation) to determine the light transmittance of the resin film at a wavelength of 400 nm.

### (Item 4: Measurement of Tg of Resin Film)

The resin film (sample) prepared in each Example was subjected to Tg measurement using a thermomechanical analyzer (EXSTAR6000 TMA/SS6000, manufactured by SII NanoTechnology Inc.). In the first step of this measurement, the sample was heated to 150° C. at a heating rate of 5° C./min to remove adsorbed water in this sample. Then, in the second step, the sample was cooled to room temperature at a cooling rate of 5° C./min. In the subsequent third step, the sample was heated at a heating rate of 5° C./min to determine the Tg.

### (Item 5: Measurement of Td₀ of Resin Film)

The resin film (sample) prepared in each Example was subjected to Td₀ measurement using a thermogravimetric analyzer (TGA-50, manufactured by Shimadzu Corporation Inc.). In the first step of this measurement, the sample was heated to 150° C. at a heating rate of 10° C./min to remove adsorbed water in this sample. Then, in the second step, the sample was cooled to room temperature at a cooling rate of 10° C./min. In the subsequent third step, the sample was heated at a heating rate of 10° C./min to determine the Td₀ of the sample.

### (Item 6: Measurement of Tensile Elongation and Maximum Tensile Stress of Resin Film)

The resin film prepared in each Example was subjected to measurement using a Tensilon universal testing machine (RTM-100, manufactured by Orientec Co., Ltd.) according to Japanese Industrial Standard (JIS K 7127: 1999). Measuring conditions were as follows: width of a test piece 10 mm, chuck interval 50 mm, test speed 50 mm/min, and number of measurements n=10.

### (Item 7: Crease Evaluation)

The resin film prepared in each Example was put on a glass substrate to produce a stack, and a SiO layer having a thickness of 50 nm was formed on the resin film by CVD and then heat-treated at 425° C. or 450° C. for 30 minutes. Subsequently, the SiO layer on the resin film was observed visually and by optical microscopy to examine whether or not creases existed. A sample was rated as C if it suffered creasing at 425° C., rated as B if it suffered creasing only at 450° C., and rated as A if it suffered no creasing.

### (Item 8: Film Lifting Evaluation)

The resin film prepared in each Example was put on a glass substrate to produce a stack, and a SiO layer having a thickness of 50 nm was formed on the resin film by CVD and then heat-treated at 450° C. for 120 minutes. Subsequently, the number of portions where the SiO layer was lifted from the resin film was determined visually and by optical microscopic observation. The evaluation covered the entire surface (350 mm long x 300 mm wide) and observation was performed at a magnification of 50 times.

### (Compounds)

Compounds as listed below were used appropriately in Examples and Comparative examples.

The name and abbreviation of each compound are as follows.
DDS: 4,4′-diaminodiphenylsulfone
PDA: p-phenylenediamine
TFMB: 2,2′-di(trifluoromethyl)-4,4′-diaminobiphenyl
DABA: 4,4′-diaminobenzanilide
DAE: 4,4′-diaminodiphenyl ether
BPDA: 3,3′,4,4′-biphenyltetracarboxylic dianhydride
DNDA: a compound having a structure as represented by the chemical formula (35)
CpODA: a compound having a structure as represented by the chemical formula (36)
3APhTMS: 3-aminophenyltrimethoxysilane
3APTMS: 3-aminopropyltrimethoxysilane
3APhDMS: 3-aminophenyldimethoxymethylsilane
PTMS: phenyltrimethoxysilane
NMP: N-methyl-2-pyrrolidone

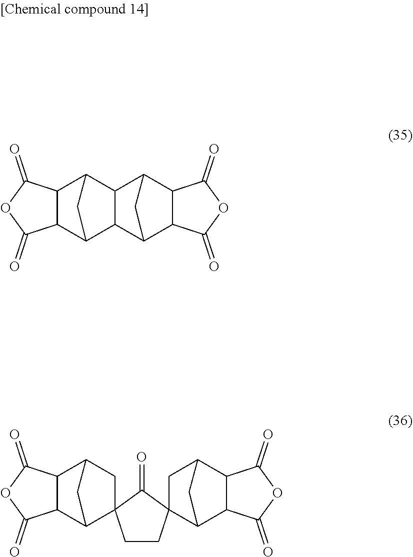 [SMILES: O=C1OC(=O)C2C3CC(C12)C1C2CC(C4C(=O)OC(=O)C24)C31 ; O=C1OC(=O)C2C1C1CC2C2(CCC3(CC4CC3C3C(=O)OC(=O)C43)C2=O)C1]

### Synthesis Example 1

A thermometer and a stirring rod equipped with stirring blades were fitted on a 300 mL four-necked flask. Then, in a dry nitrogen flow, NMP (140 g) and DDS (17.5 g (70.5 mmol)) were added, and the temperature was elevated to 50° C. After the temperature elevation, BPDA (29.6 g (100.7 mmol)) was added while stirring. After stirring for 2 hours, 3APhTMS (12.9 g (60.4 mol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 2

A thermometer and a stirring rod equipped with stirring blades were fitted on a 300 mL four-necked flask. Then, in a dry nitrogen flow, NMP (140 g) and DDS (25.7 g (103.4 mmol)) were added and the temperature was elevated to 50° C. After the temperature elevation, BPDA (32.0 g (108.8 mmol)) was added while stirring. After stirring for 2 hours, 3APhTMS (2.3 g (10.9 mmol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 3

A thermometer and a stirring rod equipped with stirring blades were fitted on a 300 mL four-necked flask. Then, in a dry nitrogen flow, NMP (140 g) and DDS (20.6 g (83.0 mmol)) were added, and the temperature was elevated to 50° C. After the temperature elevation, BPDA (30.5 g (103.8 mmol)) was added while stirring. After stirring for 2 hours, 3APhTMS (8.9 g (41.5 mol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 4

A thermometer and a stirring rod equipped with stirring blades were fitted on a 300 mL four-necked flask. Then, in a dry nitrogen flow, NMP (140 g) and DDS (16.0 g (64.5 mmol)) were added, and the temperature was elevated to 50° C. After the temperature elevation, BPDA (29.2 g (99.2 mmol)) was added while stirring. After stirring for 2 hours, 3APhTMS (14.8 g (69.4 mmol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 5

A thermometer and a stirring rod equipped with stirring blades were fitted on a 300 mL four-necked flask. Then, in a dry nitrogen flow, NMP (140 g) and DDS (25.8 g (104.0 mmol)) were added, and the temperature was elevated to 50° C. After the temperature elevation, BPDA (32.2 g (109.5 mmol)) was added while stirring. After stirring for 2 hours, 3APTMS (2.0 g (10.9 mmol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 6

A thermometer and a stirring rod equipped with stirring blades were fitted on a 300 mL four-necked flask. Then, in a dry nitrogen flow, NMP (140 g) and DDS (17.5 g (70.5 mmol)) were added, and the temperature was elevated to 50° C. After the temperature elevation, BPDA (29.6 g (100.7 mmol)) was added while stirring. After stirring for 2 hours, 3APhTMS (12.9 g (60.4 mmol)) was added. After stirring for 2 hours, the reaction solution was cooled to room temperature. Subsequently, it was diluted with NMP to adjust the viscosity to about 2,000 cP and filtered through a filter with a pore size of 0.2 μm to prepare a resin composition (varnish).

### Synthesis Example 7

A thermometer and a stirring rod equipped with stirring blades were fitted on a 300 mL four-necked flask. Then, in a dry nitrogen flow, NMP (140 g) and DDS (17.5 g (70.5 mmol)) were added, and the temperature was elevated to 50° C. After the temperature elevation, BPDA (29.6 g (100.7 mmol)) was added while stirring. After stirring for 2 hours, 3APhTMS (12.9 g (60.4 mmol)) was added. After stirring for 2 hours, Molecular Sieve 4A (10 g) was added and the temperature was elevated to 90° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 8

A thermometer and a stirring rod equipped with stirring blades were fitted on a 300 mL four-necked flask. Then, in a dry nitrogen flow, NMP (140 g) and DDS (17.5 g (70.5 mmol)) were added, and the temperature was elevated to 50° C. After the temperature elevation, BPDA (29.6 g (100.7 mmol)) was added while stirring. After stirring for 2 hours, 3APhTMS (12.9 g (60.4 mmol)) was added. After stirring for 2 hours, Molecular Sieve 4A (10 g) was added and the temperature was elevated to 70° C., followed by stirring for 6 hours. The reaction solution was cooled to room temperature and PTMS (36 g) was added, followed by stirring to provide a uniform mixture. After the end of the stirring, it was diluted with NMP to adjust the viscosity to about 2,000 cP and filtered through a filter with a pore size of 0.2 μm to prepare a resin composition (varnish).

### Synthesis Example 9

A thermometer and a stirring rod equipped with stirring blades were fitted on a 300 mL four-necked flask. Then, in a dry nitrogen flow, NMP (140 g) and DDS (27.2 g (109.4 mmol)) were added, and the temperature was elevated to 50° C. After the temperature elevation, BPDA (32.8 g (111.6 mmol)) was added while stirring. After stirring for 4 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 10

A thermometer and a stirring rod equipped with stirring blades were fitted on a 300 mL four-necked flask. Then, in a dry nitrogen flow, NMP (140 g) and TFMB (20.8 g (65.1 mmol)) were added, and the temperature was elevated to 50° C. After the temperature elevation, BPDA (27.3 g (92.9 mmol)) was added while stirring. After stirring for 2 hours, 3APhTMS (11.9 g (55.8 mmol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 11

A thermometer and a stirring rod equipped with stirring blades were fitted on a 300 mL four-necked flask. Then, in a dry nitrogen flow, NMP (140 g) and PDA (9.1 g (84.4 mmol)) were added, and the temperature was elevated to 50° C. After the temperature elevation, BPDA (35.5 g (120.5 mmol)) was added while stirring. After stirring for 2 hours, 3APhTMS (15.4 g (72.3 mmol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 12

A thermometer and a stirring rod equipped with stirring blades were fitted on a 300 mL four-necked flask. Then, in a dry nitrogen flow, NMP (140 g) and DAE (15.0 g (74.7 mmol)) were added, and the temperature was elevated to 50° C. After the temperature elevation, BPDA (31.4 g (106.7 mmol)) was added while stirring. After stirring for 2 hours, 3APhTMS (15.7 g (64.0 mmol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 13

A thermometer and a stirring rod equipped with stirring blades were fitted on a 300 mL four-necked flask. Then, in a dry nitrogen flow, NMP (140 g) and DDS (18.1 g (73.0 mmol)) were added, and the temperature was elevated to 50° C. After the temperature elevation, BPDA (30.7 g (104.2 mmol)) was added while stirring. After stirring for 2 hours, 3APTMS (11.2 g (62.5 mmol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 14

A thermometer and a stirring rod equipped with stirring blades were fitted on a 300 mL four-necked flask. Then, in a dry nitrogen flow, NMP (140 g) and DDS (7.9 g (31.9 mmol)) were added, and the temperature was elevated to 50° C. After the temperature elevation, BPDA (26.8 g (91.1 mmol)) was added while stirring. After stirring for 2 hours, 3APhTMS (25.3 g (118.5 mmol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 15

A thermometer and a stirring rod equipped with stirring blades were fitted on a 300 mL four-necked flask. Then, in a dry nitrogen flow, NMP (140 g) and DABA (16.2 g (71.3 mmol)) were added, and the temperature was elevated to 50° C. After the temperature elevation, DNDA (30.8 g (101.8 mmol)) was added while stirring. After stirring for 2 hours, 3APhTMS (13.0 g (61.1 mmol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 16

A thermometer and a stirring rod equipped with stirring blades were fitted on a 300 mL four-necked flask. Then, in a dry nitrogen flow, NMP (140 g), DABA (7.2 g (31.7 mmol)), and DAE (6.4 g (31.7 mmol)) were added, and the temperature was elevated to 50° C. After the temperature elevation, CpODA (34.8 g (90.6 mmol)) was added while stirring. After stirring for 2 hours, 3APhTMS (11.6 g (54.4 mmol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 17

A thermometer and a stirring rod equipped with stirring blades were fitted on a 300 mL four-necked flask. Then, in a dry nitrogen flow, NMP (140 g) and DABA (25.5 g (112.0 mmol)) were added, and the temperature was elevated to 50° C. After the temperature elevation, DNDA (34.5 g (114.3 mmol)) was added while stirring. After stirring for 4 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 18

A thermometer and a stirring rod equipped with stirring blades were fitted on a 300 mL four-necked flask. Then, in a dry nitrogen flow, NMP (140 g), DABA (11.3 g (49.5 mmol)), and DAE (9.9 g (49.5 mmol)) were added, and the temperature was elevated to 50° C. After the temperature elevation, CpODA (38.8 g (101.0 mmol)) was added while stirring. After stirring for 4 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

### Synthesis Example 19

A thermometer and a stirring rod equipped with stirring blades were fitted on a 300 mL four-necked flask. Then, in a dry nitrogen flow, NMP (140 g) and DDS (17.8 g (71.6 mmol)) were added, and the temperature was elevated to 50° C. After the temperature elevation, BPDA (30.1 g (102.3 mmol)) was added while stirring. After stirring for 2 hours, 3APhDMS (12.1 g (61.4 mmol)) was added. After stirring for 2 hours, Molecular Sieve 4A (10 g) was added and the temperature was elevated to 70° C., followed by stirring for 6 hours. The reaction solution was cooled to room temperature, diluted with NMP to adjust the viscosity to about 2,000 cP, and filtered through a filter with a pore size of 0.2 μm to prepare a resin composition (varnish).

The components of the resin compositions (varnishes) prepared in Synthesis examples 1 to 19 are listed in Table 1.

TABLE 1

| | precursor resin | | | | | | | | | | |
|---|---|---|---|---|---|---|---|---|---|---|---|
| | | | | molar ratio | | | | | | additive | |
| | monomer | | | | | | diamine/ | aminosilane/ | | | content [%] |
| | | tetra- | | | tetra- | | tetra- | tetra- | | | (precursor |
| Synthesis | | carboxylic | | | carboxylic | | carboxylic | carboxylic | imidization | | resin |
| example | diamine | acid | aminosilane | diamine | acid | aminosilane | acid | acid | rate [%] | additive | weight ratio) |
| Synthesis | DDS | BPDA | 3APhTMS | 70 | 100 | 60 | 0.7 | 0.6 | 18 | — | — |
| example 1 | | | | | | | | | | | |
| Synthesis | DDS | BPDA | 3APhTMS | 95 | 100 | 10 | 0.95 | 0.1 | 18 | — | — |
| example 2 | | | | | | | | | | | |
| Synthesis | DDS | BPDA | 3APhTMS | 80 | 100 | 40 | 0.8 | 0.4 | 18 | — | — |
| example 3 | | | | | | | | | | | |
| Synthesis | DDS | BPDA | 3APhTMS | 65 | 100 | 70 | 0.65 | 0.7 | 18 | — | — |
| example 4 | | | | | | | | | | | |
| Synthesis | DDS | BPDA | 3 APTMS | 95 | 100 | 10 | 0.95 | 0.1 | 18 | — | — |
| example 5 | | | | | | | | | | | |
| Synthesis | DDS | BPDA | 3APhTMS | 70 | 100 | 60 | 0.7 | 0.6 | 4 | — | — |
| example 6 | | | | | | | | | | | |
| Synthesis | DDS | BPDA | 3APhTMS | 70 | 100 | 60 | 0.7 | 0.6 | 31 | — | — |
| example 7 | | | | | | | | | | | |
| Synthesis | DDS | BPDA | 3APhTMS | 70 | 100 | 60 | 0.7 | 0.6 | 18 | PTMS | 60 |
| example 8 | | | | | | | | | | | |
| Synthesis | DDS | BPDA | — | 98 | 100 | 0 | 0.98 | 0 | 18 | — | — |
| example 9 | | | | | | | | | | | |
| Synthesis | TFMB | BPDA | 3APhTMS | 70 | 100 | 60 | 0.7 | 0.6 | 18 | — | — |
| example 10 | | | | | | | | | | | |
| Synthesis | PDA | BPDA | 3APhTMS | 70 | 100 | 60 | 0.7 | 0.6 | 18 | — | — |
| example 11 | | | | | | | | | | | |
| Synthesis | DAE | BPDA | 3APhTMS | 70 | 100 | 60 | 0.7 | 0.6 | 18 | — | — |
| example 12 | | | | | | | | | | | |
| Synthesis | DDS | BPDA | 3 APTMS | 70 | 100 | 60 | 0.7 | 0.6 | 18 | — | — |
| example 13 | | | | | | | | | | | |
| Synthesis | DDS | BPDA | 3APhTMS | 35 | 100 | 130 | 0.35 | 1.3 | 18 | — | — |
| example 14 | | | | | | | | | | | |
| Synthesis | DABA | DNDA | 3APhTMS | 70 | 100 | 60 | 0.7 | 0.6 | 18 | — | — |
| example 15 | | | | | | | | | | | |
| Synthesis | DABA | CpODA | 3APhTMS | 70 | 100 | 60 | 0.7 | 0.6 | 18 | — | — |
| example 16 | DAE | | | | | | | | | | |
| Synthesis | DABA | DNDA | — | 98 | 100 | — | 0.98 | 0 | 18 | — | — |
| example 17 | | | | | | | | | | | |
| Synthesis | DABA | CpODA | — | 98 | 100 | — | 0.98 | 0 | 18 | — | — |
| example 18 | DAE | | | | | | | | | | |
| Synthesis | DDS | BPDA | 3 APhDMS | 70 | 100 | 60 | 0.7 | 0.6 | 18 | — | — |
| example 19 | | | | | | | | | | | |

### Example 1

For the resin composition (varnish) prepared in Synthesis example 1, the viscosity change rate of the precursor resin composition was measured by the method described under Item 1 above, and the imidization rate of the precursor resin was measured by the method described under Item 2 above.

Then, using a slit coating apparatus (manufactured by Toray Engineering Co., Ltd.), the resin composition (varnish) prepared in Synthesis example 1 was spread over the surface of a non-alkali glass substrate (AN-100, manufactured by Asahi Glass Co., Ltd.) having a size of 350 mm length×300 mm width×0.5 mm thickness, leaving the 5 mm wide periphery uncoated. Then, using the same apparatus, it was heated and vacuum-dried at a temperature of 40° C. Finally, using a gas oven (INH-21 CD, manufactured by Koyo Thermo Systems Co., Ltd.), it was heated at 410° C. for 30 minutes in a nitrogen atmosphere (oxygen concentration 100 ppm or less) to form a resin film with a thickness of 10 μm on the glass substrate. The resin film formed on the substrate was subjected to measurement by the method described under Item 3 above to determine the light transmittance of the resin film.

Then, a laser beam (wavelength 308 nm) was applied through the surface of the glass substrate that was not covered with the resin film, thereby causing peeling along the interface between the substrate and the resin film. Tg of the resulting resin film was measured by the method described under Item 4 above, and Td₀ was measured by the method described under Item 5 above. The tensile elongation and maximum tensile stress were measured by the method described under Item 6 above.

In addition, before peeling the resin film from the glass substrate, the stack of the resin film and the glass substrate was subjected to a creasing evaluation by the method described under Item 7 above, and a film lifting evaluation was made by the method described under Item 8 above.

### Examples 2 to 11 and Comparative Examples 1 to 9

In Examples 2 to 11, Comparative examples 1 to 6, and Comparative examples 8 and 9, resin compositions (varnishes) prepared as described in Synthesis examples 2 to 19, which are listed in Table 1, were evaluated by the same procedure as in Example 1.

In Comparative example 7, the same procedure as in Example 1 except for using a heating temperature of 350° C. instead of 410° C. was carried out.

Evaluation results obtained in Examples 1 to 11 and Comparative examples 1 to 9 are shown in Table 2.

TABLE 2

| | | resin | | | | | | | |
|---|---|---|---|---|---|---|---|---|---|
| | | composition | | | | | | | |
| | | (varnish) | resin film | | | | | layered film | |
| | | viscosity | | | | tensile | tensile | | film |
| | | change rate | transmittance | Tg | Td₀ | elongation | maximum | creasing | lifting |
| Example | Synthesis example | [%] | [%] | [° C.] | [° C.] | percentage [%] | stress [MPa] | evaluation | evaluation |
| Example 1 | Synthesis example 1 | 3 | 71 | 382 | 451 | 20 | 150 | A | 0 |
| Example 2 | Synthesis example 2 | 1 | 68 | 372 | 445 | 22 | 180 | B | 1 |
| Example 3 | Synthesis example 3 | 2 | 71 | 378 | 449 | 21 | 150 | A | 0 |
| Example 4 | Synthesis example 4 | 4 | 72 | 377 | 450 | 19 | 140 | A | 0 |
| Example 5 | Synthesis example 5 | 2 | 68 | 371 | 441 | 21 | 160 | B | 3 |
| Example 6 | Synthesis example 6 | 25 | 71 | 382 | 451 | 20 | 160 | A | 0 |
| Example 7 | Synthesis example 7 | 21 | 71 | 382 | 450 | 21 | 150 | A | 0 |
| Example 8 | Synthesis example 8 | 3 | 75 | 380 | 450 | 20 | 160 | A | 0 |
| Example 9 | Synthesis example 15 | 5 | 85 | 393 | 445 | 19 | 170 | A | 2 |
| Example 10 | Synthesis example 16 | 4 | 82 | 396 | 441 | 20 | 160 | A | 3 |
| Example 11 | Synthesis example 19 | 1 | 70 | 378 | 450 | 21 | 170 | A | 1 |
| Comparative | Synthesis example 9 | 1 | 66 | 366 | 438 | 25 | 210 | C | 9 |
| example 1 | | | | | | | | | |
| Comparative | Synthesis example 10 | 4 | 31 | 276 | 435 | 19 | 170 | C | 12 |
| example 2 | | | | | | | | | |
| Comparative | Synthesis example 11 | 3 | 1.4 | 377 | 451 | 28 | 280 | A | 0 |
| example 3 | | | | | | | | | |
| Comparative | Synthesis example 12 | 5 | 1.3 | 267 | 442 | 20 | 170 | C | 5 |
| example 4 | | | | | | | | | |
| Comparative | Synthesis example 13 | 3 | 64 | 301 | 410 | 19 | 140 | C | 16 |
| example 5 | | | | | | | | | |
| Comparative | Synthesis example 14 | 5 | N.D.* | N.D.* | N.D.* | N.D.* | N.D.* | N.D.* | N.D.* |
| example 6 | | | | | | | | | |
| Comparative | Synthesis example 1 | 3 | 72 | 360 | 439 | 22 | 160 | C | 10 |
| example 7 | | | | | | | | | |
| Comparative | Synthesis example 17 | 3 | 84 | 379 | 425 | 24 | 200 | A | 12 |
| example 8 | | | | | | | | | |
| Comparative | Synthesis example 18 | 3 | 80 | 381 | 410 | 25 | 190 | A | 18 |
| example 9 | | | | | | | | | |

*Evaluation impossible due to crack formation

### Example 12

Except that the film thickness was 10 μm unlike Example 1 where the film thickness was 2 μm, the same procedure as in Example 1 was carried out to produce a resin film. The light transmittance of the resin film was measured by the method described under Item 3 above, and Tg was measured by the method described under Item 4 above. Tg₀ was measured by the method described under Item 5 above. The light transmittance was 83%; Tg was 378° C.; and Td₀ was 450° C.

Next, a resin film was produced on a glass substrate by the same procedure as Example 1. Then, a SiO layer having a thickness of 50 nm was formed on the resin film by CVD, and then a resin film with a thickness of 2 μm was formed on the SiO layer by the same method. For the resulting stack, a creasing evaluation was made by the method described under Item 7 above, and a film lifting evaluation was made by the method described under Item 8 above. It was rated as A in the creasing evaluation, and there was no portion that suffered film lifting in the film lifting evaluation. Thus, good results were obtained.

1. A resin film comprising a resin that has a repeating unit as represented by the chemical formula (1) and having a light transmittance of 68% or more at a wavelength of 400 nm, a glass transition temperature of 370° C. or more, and a weight loss starting temperature of 440° C. or more: 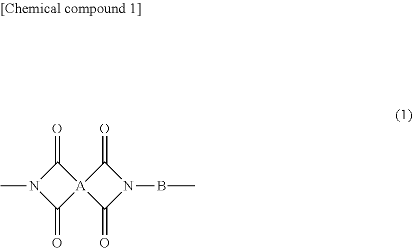
wherein, in the chemical formula (1), A denotes a tetravalent tetracarboxylic acid residue containing 2 or more carbon atoms and B denotes a divalent diamine residue containing 2 or more carbon atoms.

2. A resin film as set forth in claim 1, wherein the resin has a structure as represented by the chemical formula (2): 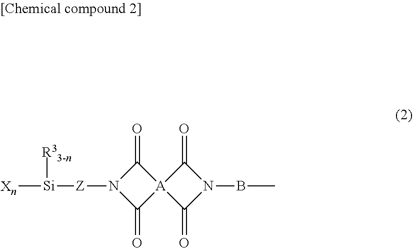
wherein, in the chemical formula (2), A denotes a tetravalent tetracarboxylic acid residue containing 2 or more carbon atoms and B denotes a divalent diamine residue containing 2 or more carbon atoms; Z denotes an aminosilane residue containing 1 to 10 carbon atoms; R³ denotes a hydrocarbon group containing 1 to 20 carbon atoms; n denotes 2 or 3; X denotes a structure as represented by the chemical formula (3); and the oxygen atom in the chemical formula (3) is bonded to the Si atom in the chemical formula (2):

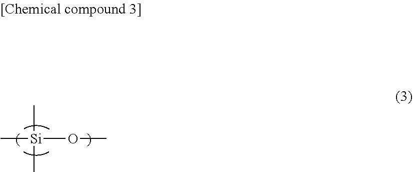

3. A resin film as set forth in claim 2, wherein the value calculated by dividing the number of moles of aminosilane residues contained in the resin by the number of moles of tetracarboxylic acid residues is 0.2 to 1.2.

4. A resin film as set forth in claim 1, wherein the value calculated by dividing the number of moles of diamine residues contained in the resin by the number of moles of tetracarboxylic acid residues is 0.4 to 0.9.

5. A resin film as set forth in a claim 2, wherein in the chemical formula (2), Z is an aromatic hydrocarbon group containing 6 to 10 carbon atoms.

6. A resin film as set forth in claim 1, wherein in the chemical formula (1), both A and B are free of fluorine atoms.

7. A resin film as set forth in claim 1, wherein in the chemical formula (1), B has a structure as represented by the chemical formula (31) and A has a structure as represented by the chemical formula (32), a structure as represented by the chemical formula (33), or a structure as represented by the chemical formula (34): 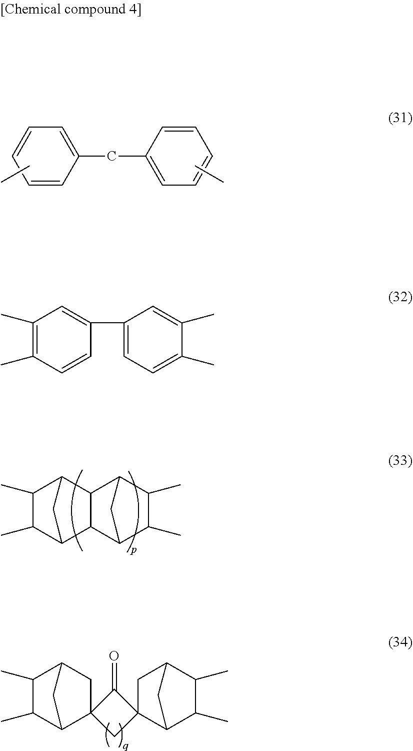
wherein in the chemical formula (31), C denotes an ether group, an ester group, an amide group, or a sulfonyl group; in the chemical formula (33), p denotes an integer of 0 to 3; and in the chemical formula (34), q denotes an integer of 1 to 4.

8. A resin film as set forth in claim 1, wherein in the chemical formula (1), A contains a 3,3′,4,4′-biphenyltetracarboxylic acid residue and B contains a 3,3′-diaminodiphenylsulfone residue or a 4,4′-diaminodiphenylsulfone residue.

9. A resin film as set forth in claim 1 that is designed to be used as a display substrate.

10. A display comprising a resin film as set forth in claim 1.

11. A resin composition comprising a resin that has a repeating unit as represented by the chemical formula (4) and a solvent and serving to form, when being spread and baked at 410° C., a 10 μm thick resin film having a light transmittance of 68% or more at a wavelength of 400 nm, a glass transition temperature of 370° C. or more, and a weight loss starting temperature of 440° C. or more: 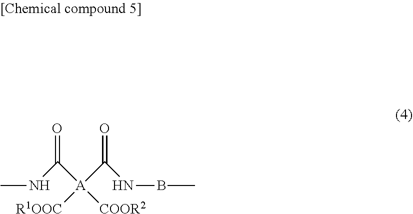
wherein, in the chemical formula (4), A denotes a tetravalent tetracarboxylic acid residue containing 2 or more carbon atoms and B denotes a divalent diamine residue containing 2 or more carbon atoms; and R¹ and R² each independently denote a hydrogen atom, a hydrocarbon group containing 1 to 10 carbon atoms, an alkyl silyl group containing 1 to 10 carbon atoms, an alkali metal ion, an ammonium ion, an imidazolium ion, or a pyridinium ion.

12. A resin composition as set forth in claim 11, wherein the resin has a structure as represented by the chemical formula (5): 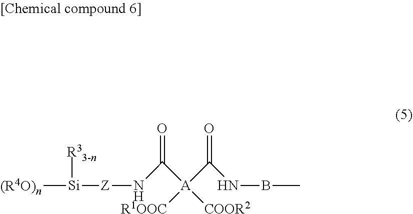
wherein, in the chemical formula (5), A denotes a tetravalent tetracarboxylic acid residue containing 2 or more carbon atoms and B denotes a divalent diamine residue containing 2 or more carbon atoms; R¹ and R² each independently denote a hydrogen atom, a hydrocarbon group containing 1 to 10 carbon atoms, an alkyl silyl group containing 1 to 10 carbon atoms, an alkali metal ion, an ammonium ion, an imidazolium ion, or a pyridinium ion; R³ and R⁴ each independently represent a hydrocarbon group containing 1 to 20 carbon atoms; and n denotes 2 or 3.

13. A resin composition as set forth in claim 11, wherein the resin has an imidization rate of 5% to 30%.

14. A resin composition as set forth in claim 11 further comprising a silane compound having a structure as represented by the chemical formula (7): 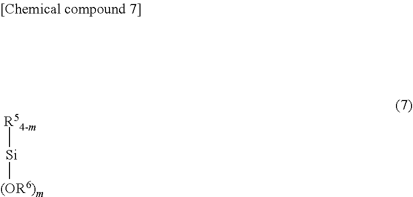
wherein in the chemical formula (7), R⁵ and R⁶ each independently denote a hydrocarbon group containing 1 to 20 carbon atoms; and m denotes 3 or 4.

15. A production method for a resin film comprising a step for coating a support with a resin composition as set forth claim 11 and baking it at 400° C. to 490° C.

16. A production method for a display comprising a step for forming a resin film on a support by a production method for a resin film as set forth in claim 15, a step for forming a display element on the resin film, and a step for peeling the resin film from the support.
